(19) United States
(12) Patent Application Publication
(10) Pub. No.: US 2023/0402575 A1
(43) Pub. Date: Dec. 14, 2023

(54) Manufacturing Method of Display Panel and Display Panel

(71) Applicant: Shenzhen China Star Optoelectronics Semiconductor Display Techonology Co., Ltd., Shenzhen (CN)

(72) Inventors: Bin ZHAO, Shenzhen (CN); Juncheng XIAO, Shenzhen (CN); Junling LIU, Shenzhen (CN)

(73) Assignee: Shenzhen China Star Optoelectronics Semiconductor Display Technology Co., Ltd., Shenzhen, GD (CN)

(21) Appl. No.: 18/011,544

(22) PCT Filed: Jun. 29, 2022
(86) PCT No.: PCT/CN2022/102233

§ 371 Date: Dec. 20, 2022

(30) Foreign Application Priority Data
Jun. 8, 2022 (CN) 202210642884.5
Jun. 29, 2022 (WO) PCT/CN2022/102233

(51) Int. Cl. H01L 33/62; H01L 25/075

(52) U.S. Cl. CPC H01L 33/62; H01L 2933/0066; H01L 25/0753

(57) ABSTRACT

Embodiments of the present application disclose a manufacturing method of a display panel and the display panel. By welding a metal film on a side of a back plate through a soldering aid layer, the soldering aid layer is converted into a welding portion, the metal film is electrically connected to a plurality of first wires through the welding portion; bending the metal film to a second surface of the back plate; and patterning the metal film and the welding portion to form a plurality of second wires, the second wires are disposed on the side and the second surface of the back plate, and the second wires are electrically connected to corresponding ones of the first wires.

### FIELD OF INVENTION

The present application relates to a field of display technology, and specifically to a manufacturing method of a display panel and the display panel.

### BACKGROUND

There are two methods to realize technical schemes of a frameless or a narrow-framed display panel, one of the methods is a side bonding method: front bonding wires are shortened or shrunk into an inside of the display panel, then a side printing process is used to form nano silver glue on a side of the display panel, the nano silver glue is connected to the front bonding wires, then the nano silver glue is patterned through a laser cutting process, and then a chip on film (COF) is bonded onto the nano silver glue located on the side of the display panel, so as to achieve an effect of narrow frame or frameless. The side bonding method can also be as follows: a conductive layer is formed on the side of the display panel by a side physical vapor deposition process, the conductive layer is connected to the front bonding wires, then the conductive layer is patterned through the laser cutting process or a mask process, and then the chip on film is bonded onto the conductive layer located on the side of the display panel, so as to achieve the effect of narrow frame or frameless. Another method is a back bonding method, wherein the front bonding wires are shortened or shrunk into the inside of the display panel, then back bonding wires are formed on a back of the display panel corresponding to the front bonding wires, then the nano silver glue is similarly formed on the side by using the side printing process or the side physical vapor deposition process, and then the nano silver glue is patterned by the laser cutting process, wherein the nano silver glue is connected to the front bonding wires and the back bonding wires, and finally, the chip on film is bonded onto the back bonding wires, so as to achieve the effect of narrow frame or frameless.

During research and practice of the prior art, inventor of the present application has found that the above two frameless or narrow-frame technologies need to be realized through the side printing process combined with the laser cutting process, or through the side physical vapor deposition process combined with the laser cutting process or the mask process, which are all complex. Wherein a precision requirement to side printing is very high, a situation of a short-circuit of a substrate or a reduction of stiffness of the substrate caused by diffusion and penetration of silver ions, or an abnormal alignment usually occurs in a manufacturing process, resulting in low yield and high cost at a same time, which makes frameless technology unable to be widely adopted and popularized.

### SUMMARY

Embodiments of the present application provide a manufacturing method of a display panel and the display panel, which can solve a complex technical problem of a traditional frameless or a narrow-frame technology.

The present application provides a manufacturing method of a display panel, which includes:
step B1: providing a metal film and a back plate, a first surface of the back plate being provided with a plurality of first wires;
step B2: disposing a soldering aid layer on the metal film, the soldering aid layer being doped with conductive particles;
step B3: attaching a side of the metal film disposed with the soldering aid layer to a side of the back plate, and performing a hot-pressing treatment on the metal film, so that the soldering aid layer is converted into a welding portion, and the metal film is electrically connected to the plurality of first wires through the welding portion;
step B4: bending the metal film to a second surface of the back plate;
step B5: patterning the metal film and the welding portion to form a plurality of second wires, the second wires being disposed on the side and the second surface of the back plate, and the second wires being electrically connected to corresponding ones of the first wires; and
step B6: disposing a plurality of light-emitting devices on the first surface of the back plate.

Alternatively, in some embodiments of the present application, after the step B2 and before the step B3, the manufacturing method of the display panel further includes:
performing a precuring treatment on the soldering aid layer.

Alternatively, in some embodiments of the present application, the conductive particles are selected from one or more of gold conductive particles, tin conductive particles, silver conductive particles, and indium conductive particles.

Alternatively, in some embodiments of the present application, in the step B3, the soldering aid layer further covers upper surfaces of the first wires.

Alternatively, in some embodiments of the present application, in the step B3, the welding portion includes a first welding portion and a second welding portion; and
in the step B3, the step of performing the hot-pressing treatment on the metal film includes:
B31: performing a first hot-pressing treatment on the metal film located on the side of the back plate, so that the soldering aid layer located on the side of the back plate is converted into the first welding portion, and the first welding portion is in contact with end surfaces of the first wires; and
B32: performing a second hot-pressing treatment on the soldering aid layer located on the first surface of the back plate, so that the soldering aid layer located on the first surface of the back plate is converted into the second welding portion, the second welding portion is in contact with the upper surfaces of the first wires, and the first welding portion and the second welding portion are electrically connected.

Alternatively, in some embodiments of the present application, in the step B3, the metal film further covers the soldering aid layer located on the first wires.

Alternatively, in some embodiments of the present application, in the step B3, the welding portion includes a first welding portion and a second welding portion; and
in the step B3, the step of performing the hot-pressing treatment on the metal film includes:
B231′: performing a first hot-pressing treatment on the metal film located on the side of the back plate, so that the soldering aid layer located on the side of the back plate is converted into the first welding portion, and the first welding portion is in contact with end surfaces of the first wires; and
B232′: performing a second hot-pressing treatment on the metal film located on the first surface of the back plate, so that the soldering aid layer located on the first surface of the back plate is converted into the second welding portion, the second welding portion is in contact with the upper surfaces of the first wires, and the first welding portion and the second welding portion are electrically connected.

Alternatively, in some embodiments of the present application, after the step B5, the manufacturing method of the display panel further includes:
bonding a chip on film onto the second wires located on the second surface of the back plate.

Alternatively, in some embodiments of the present application, after the step of bonding the chip on film onto the second wires located on the second surface of the back plate, the manufacturing method of the display panel further includes:
encapsulating the first wires, the second wires, and the chip on film.

Alternatively, in some embodiments of the present application, in the step B2, the soldering aid layer is formed by coating soldering aid flux on the metal film.

Alternatively, in some embodiments of the present application, a material of the metal film is copper foil or silver foil.

An embodiment of the present application further provides a display panel, which includes:
a back plate, wherein a first surface of the back plate is provided with a plurality of first wires; and
a plurality of second wires, wherein each of the second wires includes a wiring body and a welding portion, the wiring body is at least disposed on a side and a second surface of the back plate, the welding portion is at least disposed between the side of the back plate and the wiring body, and the wiring body is electrically connected to the first wires through the welding portion.

Alternatively, in some embodiments of the present application, the welding portion includes a first welding portion and a second welding portion, the first welding portion is connected to the second welding portion, the first welding portion is disposed between the side of the back plate and the wiring body, the first welding portion is in contact with end surfaces of the first wires, and the second welding portion covers upper surfaces of the first wires.

Alternatively, in some embodiments of the present application, the wiring body includes a first segment and a second segment, the first segment is connected to the second segment, the first segment is disposed corresponding to the side of the back plate, and the second segment is disposed corresponding to the second surface of the back plate.

Alternatively, in some embodiments of the present application, the wiring body further covers the second welding portion located on the first wires.

Alternatively, in some embodiments of the present application, the wiring body further includes a third segment, the third segment is connected to the second segment through the first segment, and the third segment covers the second welding portion.

Alternatively, in some embodiments of the present application, the display panel further includes a chip on film, the chip on film is bonded onto the second wires located on the second surface.

Alternatively, in some embodiments of the present application, the display panel further includes an encapsulation adhesive, the encapsulation adhesive covers the first wires, the second wires, and the chip on film.

Alternatively, in some embodiments of the present application, a material of the welding portion includes one or more of gold, tin, silver, and indium.

Alternatively, in some embodiments of the present application, a material of the wiring body is copper or silver.

Embodiments of the present application adopts the manufacturing method of the display panel and the display panel, wherein the metal film is soldered on the side of the back plate through the soldering aid layer, the soldering aid layer is converted into the welding portion, so that the metal film is connected to the plurality of first wires through the welding portion, then the metal film is bent to the second surface of the back plate, and finally the metal film is patterned to form the plurality of second wires. Compared with a side printing process combined with a laser cutting process to realize a frameless or a narrow-frame technology, or a side physical vapor deposition process combined with the laser cutting process or a mask process to realize the frameless or the narrow-frame technology, the manufacturing method of the present application greatly simplifies a process and reduces manufacturing difficulty, and a situation of a short-circuit of a substrate or a reduction of a stiffness of the substrate caused by a diffusion and a penetration of silver ions or an abnormal alignment will not occur, thereby effectively improving a yield of products; at a same time, nano silver glue, a side printing equipment, or a physical vapor deposition equipment is not needed to use, which greatly reduces production cost.

### BRIEF DESCRIPTION OF DRAWINGS

FIG. 1 is a schematic flow diagram of a manufacturing method of a display panel provided by an embodiment of the present application.

FIG. 2 is a schematic diagram of coating soldering aid flux on a metal film provided by the embodiment of the present application.

FIG. 3 is a first schematic diagram of attaching the metal film to a side of a back plate provided by the embodiment of the present application.

FIG. 4 is a first schematic diagram of performing a hot-pressing treatment on a soldering aid layer provided by the embodiment of the present application.

FIG. 5 is a schematic cross-sectional view diagram of bending the metal film to a second surface of the back plate provided by the embodiment of the present application.

FIG. 6 is a schematic side view diagram of bending the metal film to the second surface of the back plate provided by the embodiment of the present application.

FIG. 7 is a schematic bottom view diagram of bending the metal film to the second surface of the back plate provided by the embodiment of the present application.

FIG. 8 is a schematic side view diagram of patterning the metal film and a welding portion provided by the embodiment of the present application.

FIG. 9 is a schematic bottom view diagram of patterning the metal film and the welding portion provided by the embodiment of the present application.

FIG. 10 is a schematic diagram of bonding a chip on film onto second wires located on the second surface of the back plate provided by the embodiment of the present application.

FIG. 11 is a schematic bottom view diagram of encapsulating first wires, the second wires, and the chip on film provided by the embodiment of the present application.

FIG. 12 is a schematic cross-sectional diagram of encapsulating the first wires, the second wires, and the chip on film, and a schematic structural diagram of a first display panel provided by an embodiment of the present application.

FIG. 13 is a second schematic diagram of attaching the metal film to the side of the back plate provided by an embodiment of the present application.

FIG. 14 is a second schematic diagram of performing the hot-pressing treatment on the soldering aid layer provided by the embodiment of the present application.

FIG. 15 is a schematic structural diagram of a second display panel provided by an embodiment of the present application.

FIG. 16 is a third schematic diagram of attaching the metal film to the side of the back plate provided by an embodiment of the present application.

FIG. 17 is a third schematic diagram of performing the hot-pressing treatment on the soldering aid layer provided by an embodiment of the present application.

FIG. 18 is a schematic structural diagram of a third display panel provided by an embodiment of the present application.

### DETAILED DESCRIPTION OF EMBODIMENTS

Technical solutions in embodiments of the present application will be described clearly and completely below in combination with drawings in the embodiments of the present application. Obviously, the described embodiments are only part of the embodiments of the present application, not all of the embodiments. Based on the embodiments in the present application, all other embodiments obtained by those skilled in the art without making creative work fall within a protection scope of the present application. In addition, it should be understood that specific embodiments described herein are only for a purpose of explaining and interpreting the present application and are not intended to limit the present application. In the present application, in an absence of a contrary explanation, location words used, such as “up” and “down”, usually refer to the up and down under an actual use or a working state of devices, specifically drawing directions in the attached drawings; and words “inside” and “outside” are for outline of the devices.

Embodiments of the present application provide a manufacturing method of a display panel and the display panel. The following is a detailed description. It should be noted that an order of the description of the following embodiments is not intended to limit a preferred order of the embodiments.

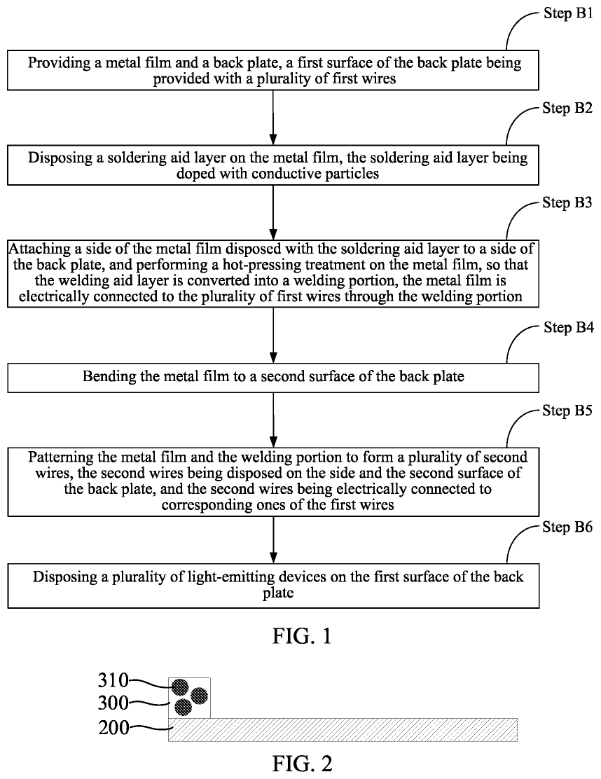

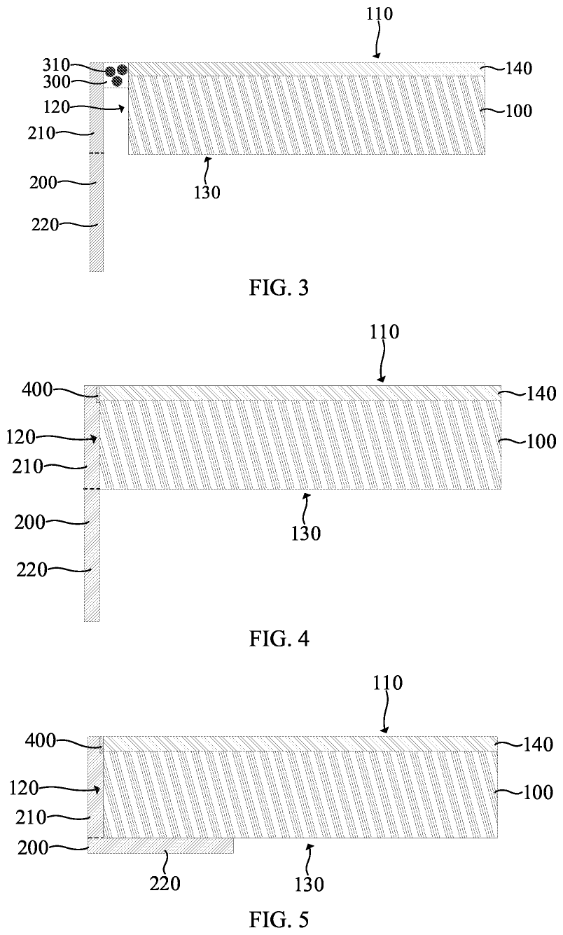

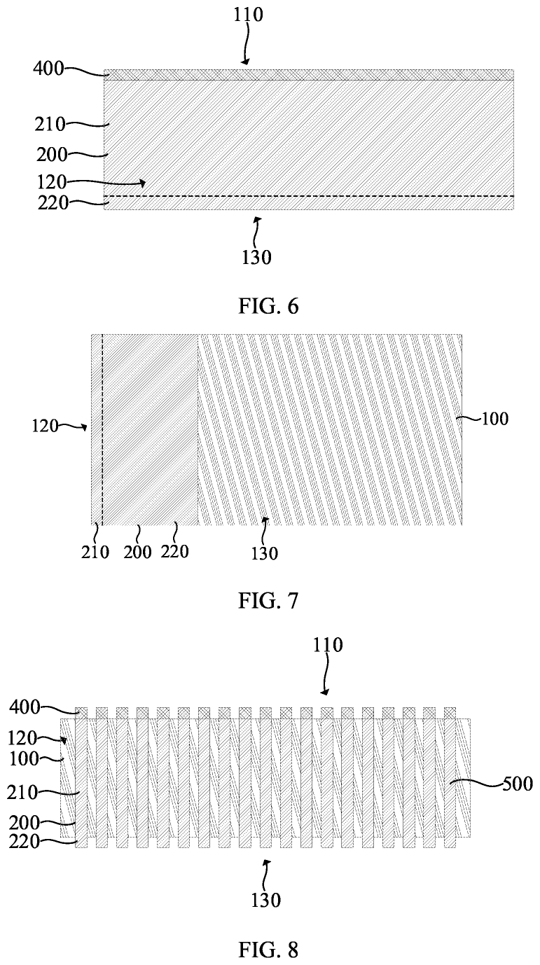

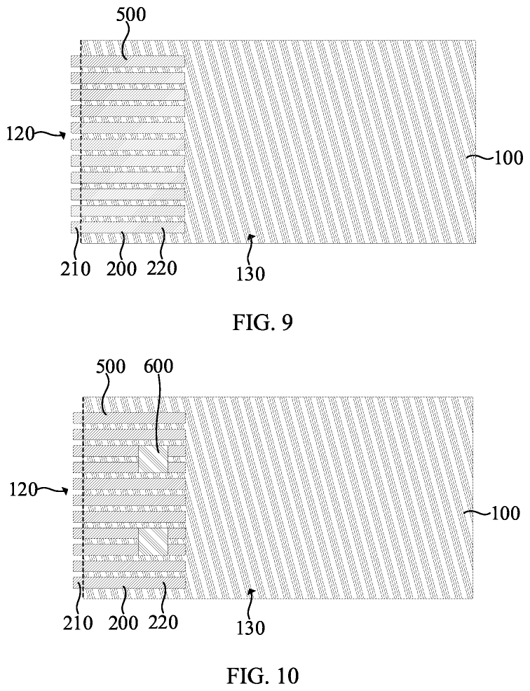

Please refer to FIG. 1, an embodiment of the present application provides the manufacturing method of the display panel, which includes:
step B1: as shown in FIG. 3, providing a metal film 200 and a back plate 100, a first surface 110 of the back plate 100 being provided with a plurality of first wires 140;
step B2: as shown in FIG. 2, disposing a soldering aid layer 300 on the metal film 200, the soldering aid layer 300 being doped with conductive particles 310;
step B3: as shown in FIG. 3 and FIG. 4, attaching a side of the metal film 200 disposed with the soldering aid layer 300 to a side 120 of the back plate 100, and performing a hot-pressing treatment on the metal film 200, so that the soldering aid layer 300 is converted into a welding portion 400, and the metal film 200 is electrically connected to the plurality of first wires 140 through the welding portion 400;
step B4: as shown in FIG. 5 to FIG. 7, bending the metal film 200 to a second surface 130 of the back plate 100;
step B5: as shown in FIG. 8 and FIG. 9, patterning the metal film 200 and the welding portion 400 to form a plurality of second wires 500, the second wires 500 being disposed on the side 120 and the second surface 130 of the back plate 100, and the second wires 500 being electrically connected to corresponding ones of the first wires 140; and
step B6: as shown in FIG. 12, disposing a plurality of light-emitting devices 150 on the first surface 110 of the back plate 100.

In the manufacturing method of the display panel according to the embodiment of the present application, the metal film 200 is soldered on the side 120 of the back plate 100, so that the metal film 200 is connected to the plurality of first wires 140 through the welding portion 400, then the metal film 200 is bent to the second surface 130 of the back plate 100, and finally the metal film 200 is patterned to form the plurality of second wires 500. Compared with a side printing process combined with a laser cutting process to realize frameless or narrow-frame technology, or a side physical vapor deposition process combined with the laser cutting process or a mask process to realize the frameless or the narrow-frame technology, the manufacturing method of the present application greatly simplifies a process and reduces manufacturing difficulty, and a situation of a short-circuit of a substrate or a reduction of stiffness of the substrate caused by diffusion and penetration of silver ions, or an abnormal alignment will not occur, thereby effectively improving yield of products; at a same time, nano silver glue, a side printing equipment, or a physical vapor deposition equipment is not needed to be used, which greatly reduces production cost.

Specifically, the display panel manufactured by the embodiment of the present application can be a mini light-emitting diode (mini LED) display panel or a micro light-emitting diode (micro LED) display panel. In this embodiment, the light-emitting device 150 can be the mini LED or the micro LED. It can be understood that the display panel can also be a liquid crystal display panel or an organic light-emitting diode display panel according to selection of an actual situation and specific requirements, and there is no unique limitation here.

Specifically, a material of the metal film 200 can be copper or silver, that is, the metal film 200 can be copper foil or silver foil. Of course, the material of the metal film 200 can be appropriately modified according to selection of an actual situation and specific requirements, and there is no unique limitation here.

Specifically, in the step B1, the step of providing the metal film 200 is specifically: forming the metal film 200 on a substrate. Specifically, the metal film 200 can be formed by physical vapor deposition or electroplating, and then the metal film 200 is stripped from the substrate to obtain the metal film 200.

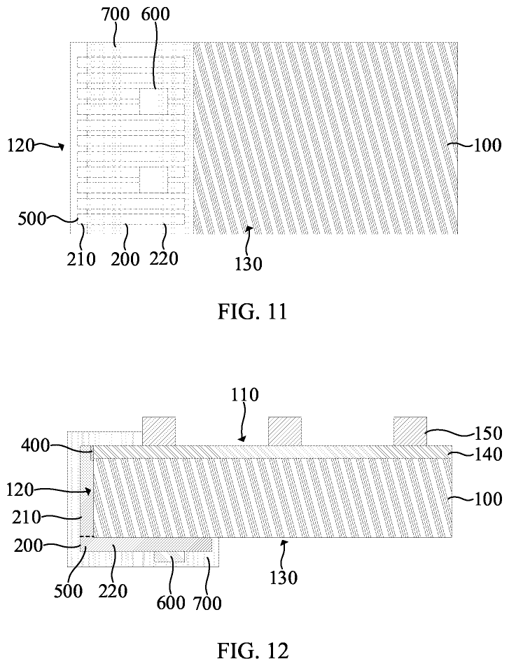

Specifically, as shown in FIG. 1, the manufacturing method of the display panel also includes:
step B51: as shown in FIG. 10 to FIG. 12, bonding a chip on film 600 onto the second wires 500 located on the second surface 130 of the back plate 100; and
step B52: encapsulating the first wires 140, the second wires 500, and the chip on film 600. In this structure, the first wires 140, the second wires 500, and the chip on film 600 are covered with an encapsulation adhesive 700, which can play a protective role and effectively prevent water vapor and oxygen erosion.

Specifically, in the step B2, the soldering aid layer 300 is formed by coating soldering aid flux on the metal film 200; in the step B3, the soldering aid layer 300 is heated to volatilize solvents in the soldering aid layer 300, then the conductive particles 310 are fused and combined together to form the welding portion 400, or the conductive particles 310, a part of the metal film 200 disposed with the soldering aid layer 300, and one end of the first wires 140 are fused and combined together to form the welding portion 400.

In the embodiment of the present application, as shown in FIG. 2, the metal film 200 includes a first segment 210 and a second segment 220, the first segment 210 is connected to the second segment 220, the first segment 210 corresponds to the side 120 of the back plate 100, and the second segment 220 corresponds to the second surface 130 of the back plate 100. In the above step B2, as shown in FIG. 3, the soldering aid layer 300 is coated on the first segment 210 of the metal film 200, and a coating position of the soldering aid layer 300 corresponds to at least end surfaces of the first wires 140. In the above step B3, as shown in FIG. 4, the first segment 210 of the metal film 200 is attached to the side 120 of the back plate 100, the soldering aid layer 300 is located between the first segment 210 and the side 120 of the back plate 100, and the soldering aid layer 300 is in contact with the end surfaces of the first wires 140. In the above step B3, as shown in FIG. 4, by performing the hot-pressing treatment on the metal film 200, the soldering aid layer 300 is also heated, so that the soldering aid layer 300 is converted into the welding portion 400. The metal film 200 is closely combined with the welding portion 400, and the welding portion 400 is closely combined with the end surfaces of the first wires 140, so that the metal film 200 is electrically connected to the plurality of first wires 140 through the welding portion 400. In the above step B4, the second segment 220 of the metal film 200 is bent to the second surface 130 of the back plate 100. In the above step B5, the second wires 500 also include the first segment 210 and the second segment 220, the first segment 210 is connected to the second segment 220, and the first segment 210 is electrically connected to the first wires 140 through the welding portion 400. In the above step B51, the chip on film 600 is bonded onto the second segment 220 of the second wires 500.

Specifically, the conductive particles 310 are selected from one or more of gold conductive particles 310, tin conductive particles 310, silver conductive particles 310, and indium conductive particles 310. It is understood that a material of the conductive particles 310 can be appropriately modified according to selection of an actual situation and specific requirements, and there is no unique limitation here.

Specifically, after the step B2 and before the step B3, the manufacturing method of the display panel also includes: performing a precuring treatment on the soldering aid layer 300. In this setting, a surface layer of the soldering aid layer 300 can be solidified, which can ensure that the soldering aid layer 300 is stably attached to the metal film 200, thereby preventing the soldering aid layer 300 from flowing, so as to facilitate implementation of the follow-up step B3.

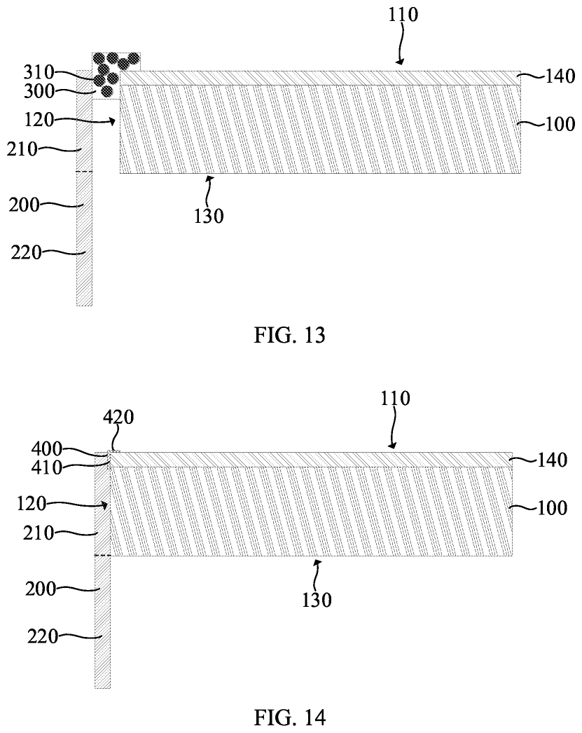

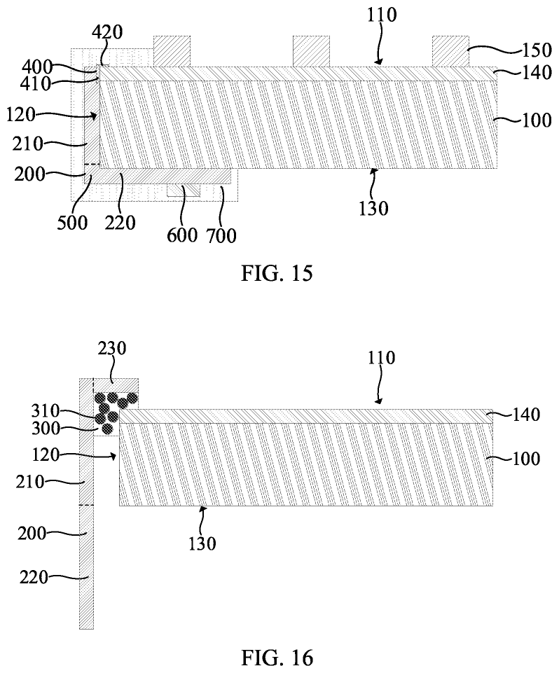

Specifically, in the step B3, as shown in FIG. 13, during a process of attaching the metal film 200 on the side 120 of the back plate 100, the soldering aid layer 300 between the first segment 210 of the metal film 200 and the side 120 of the back plate 100 is extruded, and overflows to the first surface 110 of the back plate 100, so that the soldering aid layer 300 also covers upper surfaces of the first wires 140. In this setting, in the subsequent step B3, as shown in FIG. 14, after heating the soldering aid layer 300, the formed welding portion 400 covers the end surfaces and the upper surfaces of the first wires 140, which can increase a contact area between the welding portion 400 and the first wires 140, thereby reducing contact resistance between the welding portion 400 and the first wires 140. As shown in FIG. 15, in a subsequently formed display panel, the second wires 500 are electrically connected to the first wires 140 through the welding portion 400, and the contact resistance between the welding portion 400 and the first wires 140 is less, so as to prevent an excessive signal transmission loss between the second wires 500 and the first wires 140, thereby effectively avoiding poor contact between the second wires 500 and the first wires 140.

Specifically, in the step B3, as shown in FIG. 14, the welding portion 400 includes a first welding portion 410 and a second welding portion 420, the first welding portion 410 is disposed on the side 120 of the back plate 100, and the first segment 210 of the metal film 200 and the first welding portion 410 are closely combined with the end surfaces of the first wires 140. The second welding portion 420 is disposed on the first surface 110 of the back plate 100, and the second welding portion 420 is closely combined with the upper surfaces of the first wires 140. In the step B3, the step of performing the hot-pressing treatment on the metal film 200 includes:
B31: performing a first hot-pressing treatment on the metal film 200 located on the side 120 of the back plate 100, so that the soldering aid layer 300 located on the side 120 of the back plate 100 is converted into the first welding portion 410, that is, by performing the first hot-pressing treatment on the first segment 210 of the metal film 200, so that the soldering aid layer 300 located between the first segment 210 of the metal film 200 and the side 120 of the back plate 100 is converted into the first welding portion 410, the first segment 210 of the metal film 200 is in close contact with the first welding portion 410, and the first welding portion 410 is in close contact with the end surfaces of the first wires 140; and
B32: performing a second hot-pressing treatment on the soldering aid layer 300 located on the first surface 110 of the back plate 100, so that the soldering aid layer 300 located on the first surface 110 of the back plate 100 is converted into the second welding portion 420, the first welding portion 410 and the second welding portion 420 are in close contact and electrically connected, and the second welding portion 420 is in close contact with the upper surfaces of the first wires 140. In this setting, the metal film 200, the soldering aid layer 300, and the second wires 500 can be closely combined to effectively improve welding strength. At a same time, the soldering aid layer 300 can be fully solidified to effectively prevent the excessive signal transmission loss between the second wires 500 and the first wires 140, and effectively avoid poor contact between the second wires 500 and the first wires 140.

In the step B31, by performing the first hot-pressing treatment on the metal film 200 located on the side 120 of the back plate 100, the conductive particles 310 located on the side 120 of the back plate 100 are fused and combined together to form the first welding portion 410, or the conductive particles 310 located on the side 120 of the back plate 100, a part of the first segment 210 disposed with the soldering aid layer 300, and the one end of the first wires 140 are fused and combined together to form the first welding portion 410. In the step B32, by performing the second hot-pressing treatment on the soldering aid layer 300 located on the first surface 110 of the back plate 100, the conductive particles 310 located on the first surface 110 of the back plate 100 are fused and combined together to form the second welding portion 420, or the conductive particles 310 located on the first surface 110 of the back plate 100 and the one end of the first wires 140 are fused and combined together to form the second welding portion 420.

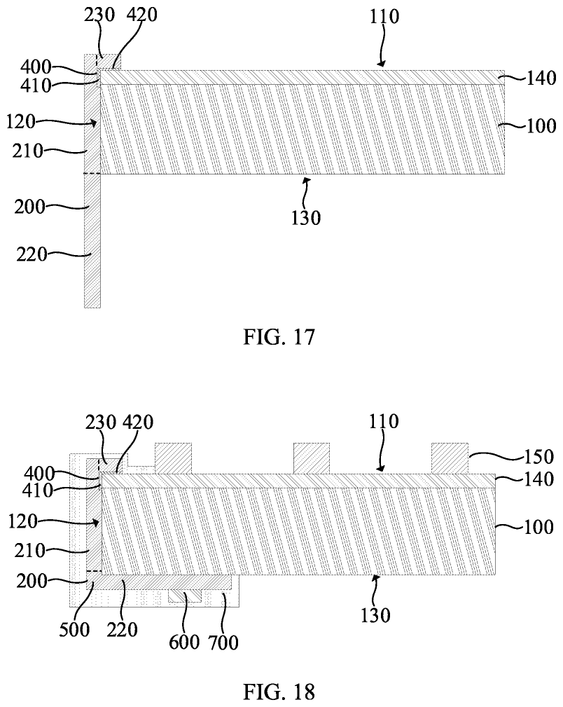

Specifically, in the step B3, as shown in FIG. 16, in the process of attaching the metal film 200 on the side 120 of the back plate 100, the metal film 200 also covers the soldering aid layer 300 located on the first wires 140. In this setting, in the subsequent step B3, as shown in FIG. 17, after heating the soldering aid layer 300, the formed welding portion 400 also covers the upper surfaces of the first wires 140, which can increase the contact area between the welding portion 400 and the first wires 140, thereby reducing the contact resistance between the welding portion 400 and the first wires 140. At a same time, the metal film 200 also covers the welding portion 400 located on the first wires 140, which can increase a contact area between the welding portion 400 and the metal film 200 and reduce contact resistance between the welding portion 400 and the metal film 200. As shown in FIG. 18, in the subsequently formed display panel, the second wires 500 are electrically connected to the first wires 140 through the welding portion 400, the contact resistance between the welding portion 400 and the first wires 140 is less, and the contact resistance between the welding portion 400 and the second wires 500 is less, so as to prevent the excessive signal transmission loss between the second wires 500 and the first wires 140, and effectively avoid poor contact between the second wires 500 and the first wires 140.

Specifically, as shown in FIG. 16, the metal film 200 also includes a third segment 230, the third segment 230 is connected to the first segment 210. Specifically, one end of the first segment 210 is connected to the second segment 220, and another end of the first segment 210 is connected to the third segment 230, that is, the third segment 230 is connected to the second segment 220 through the first segment 210. In the step B3, as shown in FIG. 16, in the process of attaching the metal film 200 on the side 120 of the back plate 100, the first segment 210 of the metal film 200 is disposed corresponding to the side 120 of the back plate 100, the third segment 230 of the metal film 200 is disposed corresponding to the first surface 110 of the back plate 100, the soldering aid layer 300 is disposed between the first segment 210 and the side 120 of the back plate 100, and between the third segment 230 and the first surface 110 of the back plate 100, and the third segment 230 specifically covers the soldering aid layer 300 located on the first wires 140. In the step B3, as shown in FIG. 17, by heating the soldering aid layer 300 located between the first segment 210 and the side 120 of the back plate 100, the soldering aid layer 300 located between the first segment 210 and the side 120 of the back plate 100 is converted into the first welding portion 410, and by heating the soldering aid layer 300 located between the third segment 230 and the first surface 110 of the back plate 100, the soldering aid layer 300 between the third segment 230 and the first surface 110 of the back plate 100 is converted into the second welding portion 420.

Specifically, in the step B3, as shown in FIG. 17, the welding portion 400 includes the first welding portion 410 and the second welding portion 420, the first welding portion 410 is disposed on the side 120 of the back plate 100, and the first segment 210 of the metal film 200 and the first welding portion 410 are closely combined with the end surfaces of the first wires 140. The second welding portion 420 is disposed on the first surface 110 of the back plate 100, and the third segment 230 of the metal film 200 and the second welding portion 420 are closely combined with the upper surfaces of the first wires 140. In the step B3, the step of performing the hot-pressing treatment on the metal film 200 includes:
B31′: performing the first hot-pressing treatment on the metal film 200 located on the side 120 of the back plate 100, so that the soldering aid layer 300 located on the side 120 of the back plate 100 is converted into the first welding portion 410, that is, by performing the first hot-pressing treatment on the first segment 210 of the metal film 200, the soldering aid layer 300 located between the first segment 210 of the metal film 200 and the side 120 of the back plate 100 is converted into the first welding portion 410, the first segment 210 of the metal film 200 is in close contact with the first welding portion 410, and the first welding portion 410 is in close contact with the end surfaces of the first wires 140; and
B32′: performing the second hot-pressing treatment on the metal film 200 located on the first surface 110 of the back plate 100, so that the soldering aid layer 300 located on the first surface 110 of the back plate 100 is converted into the second welding portion 420, that is, by performing the second hot-pressing treatment on the third segment 230 of the metal film 200, the soldering aid layer 300 located between the third segment 230 of the metal film 200 and the first surface 110 of the back plate 100 is converted into the second welding portion 420, the first welding portion 410 and the second welding portion 420 are in close contact and electrically connected, the third segment 230 of the metal film 200 is in close contact with the second welding portion 420, and the second welding portion 420 is in close contact with the upper surfaces of the first wires 140.

In the step B31′, by performing the first hot-pressing treatment on the metal film 200 located on the side 120 of the back plate 100, the conductive particles 310 located on the side 120 of the back plate 100 are fused and combined together to form the first welding portion 410, or the conductive particles 310 located on the side 120 of the back plate 100, the part of the first segment 210 disposed with the soldering aid layer 300, and the one end of the first wires 140 are fused and combined together to form the first welding portion 410. In the step B32′, by performing the second hot-pressing treatment on the metal film 200 located on the first surface 110 of the back plate 100, the conductive particles 310 located on the first surface 110 of the back plate 100 are fused and combined together to form the second welding portion 420, or the conductive particles 310 located on the first surface 110 of the back plate 100, the third segment 230, and the one end of the first wires 140 are fused and combined together to form the second welding portion 420.

In the manufacturing method of the display panel according to the embodiment of the present application, after performing the first hot-pressing treatment on the first segment 210 of the metal film 200, the part of the first segment 210 of the metal film 200 disposed with the soldering aid layer 300 can be fused and combined with the end surfaces of the first wires 140 through a crystallization layer, while a part of the first segment 210 of the metal film 200 not disposed with the soldering aid layer 300 is fused and combined with the side 120 of the back plate 100. Similarly, after performing the second hot-pressing treatment on the third segment 230 of the metal film 200, the part of the third segment 230 of the metal film 200 disposed with the soldering aid layer 300 can be fused and combined with the upper surfaces of the first wires 140, while the part of the third segment 230 of the metal film 200 not disposed with the soldering aid layer 300 is fused and combined with the upper surfaces of the first wires 140.

Specifically, after the step B4 and before the step B5, the manufacturing method of the display panel also includes:
performing a third hot-pressing treatment on the metal film 200 located on the second surface 130 of the back plate 100, so that the metal film 200 located on the second surface 130 of the back plate 100 is fused and combined on the second surface 130 of the back plate 100, that is, by performing the third hot-pressing treatment on the second segment 220 of the metal film 200, the second segment 220 of the metal film 200 is fused and combined to the second surface 130 of the back plate 100.

Referring to FIG. 12, an embodiment of the present application also provides a display panel, the display panel is manufactured by the above manufacturing method. The display panel includes the back plate 100 and the plurality of second wires 500, and the first surface 110 of the back plate 100 is provided with the plurality of first wires 140. The second wires 500 includes a wiring body 200 and the welding portion 400. The wiring body 200 is at least disposed between the side 120 of the back plate 100 and the second surface 130. The welding portion 400 is at least disposed between the side 120 of the back plate 100 and the wiring body 200. The wiring body 200 is electrically connected to the first wires 140 through the welding portion 400.

It should be noted that the wiring body 200 is the metal film 200 of the above embodiment, and the wiring body 200 will not be repeatedly explained later.

Specifically, the display panel manufactured by the embodiment of the present application can be the mini LED display panel or the micro LED display panel. In this embodiment, the first surface 110 of the back plate 100 is also provided with the plurality of light-emitting devices 150, the light-emitting devices 150 can be mini LEDs or micro LEDs. It can be understood that the display panel can also be the liquid crystal display panel or the organic light-emitting diode display panel according to selection of an actual situation and specific requirements, and there is no unique limitation here.

Specifically, as shown in FIG. 15, the welding portion 400 includes the first welding portion 410 and the second welding portion 420, the first welding portion 410 is connected to the second welding portion 420, the first welding portion 410 is disposed between the side 120 of the back plate 100 and the wiring body 200, the first welding portion 410 is in close contact with end surfaces of the first wires 140, and the second welding portion 420 covers upper surfaces of the first wires 140.

Specifically, the wiring body 200 includes the first segment 210 and the second segment 220, the first segment 210 is connected to the second segment 220, the first segment 210 is disposed corresponding to the side 120 of the back plate 100, and the second segment 220 is disposed corresponding to the second surface 130 of the back plate 100. The first segment 210 of the wiring body 200 is in close contact with the first welding portion 410, and the first welding portion 410 is in close contact with the end surfaces of the first wires 140. The first welding portion 410 and the second welding portion 420 are in close contact and are electrically connected, and the second welding portion 420 is in close contact with the upper surfaces of the first wires 140. In this structure, the second wires 500 are electrically connected to the first wires 140 through the welding portion 400, and contact resistance between the welding portion 400 and the first wires 140 is less, so as to prevent the excessive signal transmission loss between the second wires 500 and the first wires 140, and effectively avoid poor contact between the second wires 500 and the first wires 140.

Specifically, as shown in FIG. 18, the wiring body 200 also covers the second welding portion 420 located on the first wires 140. In this structure, the wiring body 200 also covers the second welding portion 420 located on the first wires 140, which can increase a contact area between the welding portion 400 and the wiring body 200, thereby reducing contact resistance between the welding portion 400 and the wiring body 200. The second wires 500 are electrically connected to the first wires 140 through the welding portion 400. The contact resistance between the welding portion 400 and the first wires 140 is less, and the contact resistance between the welding portion 400 and the second wires 500 is less, so as to prevent the excessive signal transmission loss between the second wires 500 and the first wires 140, and effectively avoid poor contact between the second wires 500 and the first wires 140.

Specifically, as shown in FIG. 18, the wiring body 200 also includes the third segment 230, the third segment 230 is connected to the first segment 210. Specifically, one end of the first segment 210 is connected to the second segment 220, and another end of the first segment 210 is connected to the third segment 230, that is, the third segment 230 is connected to the second segment 220 through the first segment 210. The third segment 230 covers the second welding portion 420 located on the first wires 140.

Specifically, the display panel also includes the chip on film 600, the chip on film 600 is disposed on the second surface 130 of the back plate 100, and is bonded onto the second wires 500 of the second surface 130 of the back plate 100, and specifically bonded onto the second segment 220 of the wiring body 200 of the second wires 500.

Specifically, the display panel also includes the encapsulation adhesive 700, the encapsulation adhesive 700 covers the first wires 140, the second wires 500, and the chip on film 600, and can play a protective role and effectively prevent water vapor and oxygen erosion.

Specifically, the material of the welding portion 400 includes one or more of gold, tin, silver, and indium. It can be understood that the material of the welding portion 400 can be appropriately modified according to selection of an actual situation and specific requirements, and there is no unique limitation here.

Specifically, a material of the wiring body 200 can be copper or silver, that is, the wiring body 200 can be copper foil or silver foil. Of course, the material of the wiring body 200 can be appropriately modified according to an actual situation and specific requirements, and there is no unique limitation here.

The above describes the manufacturing method of the display panel and the display panel provided by the embodiments of the present application in detail. In this paper, specific examples are used to explain a principle and an implementation mode of the present application. The description of the above embodiments is only used to help understand a method and a core idea of the present application. At a same time, for those skilled in the art, according to the idea of the present application, there will be changes in a specific implementation mode and a scope of application. In conclusion, contents of the specification should not be understood as restrictions on the present application.

What is claimed is:

1. A manufacturing method of a display panel, comprising:
step B1: providing a metal film and a back plate, a first surface of the back plate being provided with a plurality of first wires;
step B2: disposing a soldering aid layer on the metal film, the soldering aid layer being doped with conductive particles;
step B3: attaching a side of the metal film disposed with the soldering aid layer to a side of the back plate, and performing a hot-pressing treatment on the metal film, so that the soldering aid layer is converted into a welding portion, and the metal film is electrically connected to the plurality of first wires through the welding portion;
step B4: bending the metal film to a second surface of the back plate;
step B5: patterning the metal film and the welding portion to form a plurality of second wires, the second wires being disposed on the side and the second surface of the back plate, and the second wires being electrically connected to corresponding ones of the first wires; and
step B6: disposing a plurality of light-emitting devices on the first surface of the back plate.

2. The manufacturing method of the display panel according to claim 1, wherein after the step B2 and before the step B3, the manufacturing method of the display panel further comprises:
performing a precuring treatment on the soldering aid layer.

3. The manufacturing method of the display panel according to claim 1, wherein the conductive particles are selected from one or more of gold conductive particles, tin conductive particles, silver conductive particles, and indium conductive particles.

4. The manufacturing method of the display panel according to claim 1, wherein in the step B3, the soldering aid layer further covers upper surfaces of the first wires.

5. The manufacturing method of the display panel according to claim 4, wherein in the step B3, the welding portion comprises a first welding portion and a second welding portion; and
in the step B3, the step of performing the hot-pressing treatment on the metal film comprises:
B31: performing a first hot-pressing treatment on the metal film located on the side of the back plate, so that the soldering aid layer located on the side of the back plate is converted into the first welding portion, and the first welding portion is in contact with end surfaces of the first wires; and
B32: performing a second hot-pressing treatment on the soldering aid layer located on the first surface of the back plate, so that the soldering aid layer located on the first surface of the back plate is converted into the second welding portion, the second welding portion is in contact with the upper surfaces of the first wires, and the first welding portion and the second welding portion are electrically connected.

6. The manufacturing method of the display panel according to claim 4, wherein in the step B3, the metal film further covers the soldering aid layer located on the first wires.

7. The manufacturing method of the display panel according to claim 6, wherein in the step B3, the welding portion comprises a first welding portion and a second welding portion; and
in the step B3, the step of performing the hot-pressing treatment on the metal film comprises:
B31′: performing a first hot-pressing treatment on the metal film located on the side of the back plate, so that the soldering aid layer located on the side of the back plate is converted into the first welding portion, and the first welding portion is in contact with end surfaces of the first wires; and
B32′: performing a second hot-pressing treatment on the metal film located on the first surface of the back plate, so that the soldering aid layer located on the first surface of the back plate is converted into the second welding portion, the second welding portion is in contact with the upper surfaces of the first wires, and the first welding portion and the second welding portion are electrically connected.

8. The manufacturing method of the display panel according to claim 1, wherein after the step B5, the manufacturing method of the display panel further comprises:
bonding a chip on film onto the second wires located on the second surface of the back plate.

9. The manufacturing method of the display panel according to claim 8, wherein after the step of bonding the chip on film onto the second wires located on the second surface of the back plate, the manufacturing method of the display panel further comprises:
encapsulating the first wires, the second wires, and the chip on film.

10. The manufacturing method of the display panel according to claim 1, wherein in the step B2, the soldering aid layer is formed by coating soldering aid flux on the metal film.

11. The manufacturing method of the display panel according to claim 1, wherein a material of the metal film is copper foil or silver foil.

12. A display panel, comprising:
a back plate, wherein a first surface of the back plate is provided with a plurality of first wires; and
a plurality of second wires, wherein each of the second wires comprises a wiring body and a welding portion, the wiring body is at least disposed on a side and a second surface of the back plate, the welding portion is at least disposed between the side of the back plate and the wiring body, and the wiring body is electrically connected to the first wires through the welding portion.

13. The display panel according to claim 12, wherein the welding portion comprises a first welding portion and a second welding portion, the first welding portion is connected to the second welding portion, the first welding portion is disposed between the side of the back plate and the wiring body, the first welding portion is in contact with end surfaces of the first wires, and the second welding portion covers upper surfaces of the first wires.

14. The display panel according to claim 13, wherein the wiring body comprises a first segment and a second segment, the first segment is connected to the second segment, the first segment is disposed corresponding to the side of the back plate, and the second segment is disposed corresponding to the second surface of the back plate.

15. The display panel according to claim 14, wherein the wiring body further covers the second welding portion located on the first wires.

16. The display panel according to claim 15, wherein the wiring body further comprises a third segment, the third segment is connected to the second segment through the first segment, and the third segment covers the second welding portion.

17. The display panel according to claim 12, wherein the display panel further comprises a chip on film, the chip on film is bonded onto the second wires located on the second surface.

18. The display panel according to claim 17, wherein the display panel further comprises an encapsulation adhesive, the encapsulation adhesive covers the first wires, the second wires, and the chip on film.

19. The display panel according to claim 12, wherein a material of the welding portion comprises one or more of gold, tin, silver, and indium.

20. The display panel according to claim 12, wherein a material of the wiring body is copper or silver.
